(19) United States
(12) Patent Application Publication
(10) Pub. No.: US 2025/0040297 A1
(43) Pub. Date: Jan. 30, 2025

(54) MICRO LIGHT-EMITTING DIODE AND PREPARATION METHOD THEREFOR, MICRO LIGHT-EMITTING ELEMENT AND DISPLAY

(71) Applicant: Quanzhou sanan semiconductor technology Co., Ltd., Fujian (CN)

(72) Inventors: Zheng WU, Fujian (CN); Chia-En LEE, Fujian (CN)

(73) Assignee: Quanzhou sanan semiconductor technology Co., Ltd., Fujian (CN)

(21) Appl. No.: 18/716,941

(22) PCT Filed: Nov. 21, 2022
(86) PCT No.: PCT/CN2022/133137

§ 371 Date: Jun. 6, 2024

(30) Foreign Application Priority Data
Dec. 10, 2021 (CN) 202111510374.4

(51) Int. Cl. H01L 33/12; H01L 25/16; H01L 33/00; H01L 33/22

(52) U.S. Cl. CPC H01L 33/12; H01L 33/0095; H01L 33/22; H01L 25/167; H01L 2933/0025

(57) ABSTRACT

A micro light-emitting diode and a preparation method therefor, a micro light-emitting element and a display. The micro light-emitting diode comprises an epitaxial layer and a dielectric layer, wherein the epitaxial layer comprises a first semiconductor layer, an active layer and a second semiconductor layer which are arranged in sequence, and has a first surface and a second surface which are arranged opposite each other, the first semiconductor layer being located on the side of the epitaxial layer close to the first surface; the epitaxial layer is configured with a mesa, and the mesa is exposed from the first semiconductor layer and faces the second surface; and the dielectric layer covers the first surface and at least part of a side wall of the epitaxial layer, and the height H₁ of the dielectric layer on the side wall of the epitaxial layer is less than the height of the mesa.

### TECHNICAL FIELD

The present application relates to the field of semiconductor technology, and in particular, to a micro light-emitting diode and a preparation method therefore, a micro light-emitting element, and a display.

### DESCRIPTION OF RELATED ART

Micro light-emitting diodes have the advantages of low power consumption, high brightness, ultra-high resolution and color saturation, fast response speed, and long life, and they are currently a popular next-generation display technology in research. Mass transfer technology is an indispensable link in micro light-emitting diode display technology, and it mainly transfers micro light-emitting diodes to a specific substrate and assembles them into a two-dimensional periodic array.

Laser mass transfer technology is a relatively commonly used mass transfer technology, which includes the following processes:

1) One side of the micro light-emitting diode is connected to the substrate through an adhesive film, and the adhesive film can be peeled off under laser.

2) The other side of the micro light-emitting diode is bonded to the base with the driving circuit, the substrate is separated from the micro light-emitting diode using a laser lift-off process, and the adhesive film is removed.

The micro light-emitting diode includes a thin epitaxial layer, and the epitaxial layer has a roughened light-emitting surface. The side of the micro light-emitting diode close to the light-emitting surface is connected to the substrate through the adhesive film, and the side away from the light-emitting surface is bonded to the base having the driving circuit. During the bonding process between the micro light-emitting diode and the base, the epitaxial layer needs to withstand greater stress. Further, the above-mentioned stress is released during the separation process of the substrate and the micro light-emitting diode, which may easily cause defects of cracks and the like in the epitaxial layer or further expand coarsening damage in the light-emitting surface. During the process of removing the adhesive film, the abovementioned defects of cracks and the like or coarsening damage may further expand, causing the micro light-emitting diode to fail.

### BRIEF SUMMARY OF THE INVENTION

### Technical Problems

### Solutions to Problems

### Technical Solutions

The present application aims to provide a micro light-emitting diode in which a dielectric layer is arranged on a first surface of an epitaxial layer thereof and the dielectric layer can serve as a stress recovery layer, such that during separation of a substrate from the micro light-emitting diode by using a laser lift-off process, the defects of cracks and the like of the epitaxial layer are avoided, or coarsening damage caused by an etching process to the epitaxial layer is prevented from further expanding, and the reliability of the micro light-emitting diode is improved.

The present application also aims to provide a preparation method for a micro light-emitting diode, a micro light-emitting element, and a display.

In the first aspect, an embodiment of the present application provides a micro light-emitting diode, including:
an epitaxial layer including a first semiconductor layer, an active layer, and a second semiconductor layer arranged in sequence, where the epitaxial layer has a first surface and a second surface arranged opposite each other, the first semiconductor layer is located on a side of the epitaxial layer close to the first surface, the epitaxial layer is configured with a mesa, and the mesa is exposed from the first semiconductor layer and faces the second surface; and
a dielectric layer covering the first surface and at least a portion of a side wall of the epitaxial layer, where a height H₁ of the dielectric layer on the side wall of the epitaxial layer is less than a height of the mesa.

In an implementation, the height H₁ of the dielectric layer on the side wall of the epitaxial layer is greater than or equal to 2 μm and less than or equal to 6 μm.

In an implementation, a thickness D₁ of the dielectric layer on the side wall of the epitaxial layer is 0 to 2 μm.

In an implementation, a thickness D₂ of the dielectric layer on the first surface is greater than or equal to 0.03 μm and less than or equal to 2 μm.

In an implementation, a material of the dielectric layer includes silicon oxide, silicon nitride, titanium oxide, aluminum oxide, or magnesium fluoride.

In an implementation, at least a partial region of the first surface is configured as a rough region formed by a regular or irregular pattern, and the rough region is formed after a portion of the epitaxial layer is removed.

In an implementation, the first surface includes a rough portion and a platform portion, the platform portion surrounds a periphery of the rough portion, and the rough portion is recessed toward the second surface relative to the platform portion.

In an implementation, the micro light-emitting diode further includes:
a first insulating layer covering the second surface and at least a portion of the side wall of the epitaxial layer; and
a step structure including a first step formed by the dielectric layer and a second step formed by the first insulating layer, wherein the first step exceeds the second step in a horizontal direction, and a width of the first step exceeding the second step is equal to the thickness D₁ of the dielectric layer on the side wall of the epitaxial layer.

In an implementation, the micro light-emitting diode further includes:
a first electrode electrically connected to the first semiconductor layer; and
a second electrode electrically connected to the second semiconductor layer.

In an implementation, side walls of the first electrode and the second electrode are partially or entirely covered with a second insulating layer, and a thickness of the second insulating layer decreases in a height direction.

In an implementation, a minimum size of the micro light-emitting diode is 0.5 to 5 μm, 5 to 10 μm, 10 to 20 μm, 20 to 50 μm, or 50 to 100 μm.

In an implementation, a thickness of the epitaxial layer is 1 to 5 μm.

In an implementation, an angle α₁ between the portion of the side wall of the epitaxial layer covered by the dielectric layer and a vertical surface is between 0° and 45°, or the angle between the portion of the side wall of the epitaxial layer covered by the dielectric layer and the vertical surface is between −30° and 0°.

In the second aspect, an embodiment of the present application provides a preparation method for a micro light-emitting diode, including:
forming an epitaxial layer including a first semiconductor layer, an active layer, and a second semiconductor layer arranged in sequence, where the epitaxial layer has a first surface and a second surface arranged opposite each other, and the first semiconductor layer is located on a side of the epitaxial layer close to the first surface;
etching the epitaxial layer from the second surface and forming a mesa, where the mesa is exposed from the first semiconductor layer and faces the second surface; and
forming a dielectric layer covering the first surface and extending from the first surface to a side wall of the epitaxial layer, where a height H₁ of the dielectric layer on the side wall of the epitaxial layer is less than a height of the mesa.

In an implementation, before the dielectric layer is formed and after the epitaxial layer is etched and the mesa is formed, further including:
performing a removal process, roughening treatment, or patterning treatment on an entire region or a partial region of the first surface.

In the third aspect, an embodiment of the present application provides a micro light-emitting element, including:
a substrate;
at least one micro light-emitting diode arranged on the substrate, each of the micro light-emitting diode including:
an epitaxial layer including a first semiconductor layer, an active layer, and a second semiconductor layer arranged in sequence, where the epitaxial layer has a first surface and a second surface arranged opposite each other, the first semiconductor layer is located on a side of the epitaxial layer close to the first surface, the epitaxial layer is configured with a mesa, the mesa is exposed from the first semiconductor layer and faces the second surface, and the first surface faces or faces away from the substrate;
a dielectric layer covering the first surface and at least a portion of a side wall of the epitaxial layer, where a height H₁ of the dielectric layer on the side wall of the epitaxial layer is less than a height of the mesa; and
an adhesive film located between the substrate and the micro light-emitting diode, where a width of the adhesive film is less than a width of the epitaxial layer.

In an implementation, the substrate includes a transparent substrate, and the transparent substrate includes a sapphire substrate or a glass substrate.

In an implementation, the height H₁ of the dielectric layer on the side wall of the epitaxial layer is greater than or equal to 2 μm and less than or equal to 6 μm, a thickness D₁ of the dielectric layer on the side wall of the epitaxial layer is 0 to 2 μm, and a thickness D₂ of the dielectric layer on the first surface is greater than or equal to 0.03 μm and less than or equal to 2 μm.

In an implementation, at least a partial region of the first surface is configured as a rough region formed by a regular or irregular pattern, and the rough region is formed after a portion of the epitaxial layer is removed.

In the fourth aspect, the present application provides a display including a base having a driving circuit and at least one micro light-emitting diode arranged on the base according to the abovementioned embodiments. The micro light-emitting diode is electrically connected to the driving circuit.

### BENEFICIAL EFFECTS OF INVENTION

### Beneficial Effects

Compared to the related art, the beneficial effects of the present application include the following.

1) The dielectric layer is arranged on the first surface of the epitaxial layer and can serve as a stress recovery layer, such that during the separation of a substrate from the micro light-emitting diode by using a laser lift-off process, the defects of cracks and the like of the epitaxial layer are avoided, or coarsening damage caused by an etching process to the epitaxial layer is prevented from further expanding, and the reliability of the micro light-emitting diode is thus improved.

2) The micro light-emitting diode is configured with the step structure, and the step structure includes the first step and the second step. Herein, the first step is formed by the dielectric layer, and the second step is formed by the first insulating layer. The first step exceeds the second step in the horizontal direction, and the length of the first step exceeding the second step is equal to the thickness D1 of the dielectric layer on the side wall of the epitaxial layer. During the removal of the adhesive film, the step structure may be used to protect the first insulating layer, prevent the first insulating layer and the epitaxial layer from being damaged, and improve the reliability of the micro light-emitting diode. Further, the height of the dielectric layer on the side wall of the epitaxial layer is required to be less than the height of the mesa and the thickness of the dielectric layer on the side wall of the epitaxial layer is relatively thin, so when the second surface of the micro light-emitting diode is bonded to the substrate through the anisotropic conductive film (ACF), the anisotropic conductive film (ACF) is prevented from swelling, and the light-emitting effect of the micro light-emitting diode is improved.

### BRIEF DESCRIPTION OF THE DRAWINGS

In order to explain the technical solutions of the embodiments of the present application more clearly, the accompanying drawings required to be used in the embodiments are briefly introduced in the following paragraphs. It should be understood that the following accompanying drawings illustrate only certain embodiments of the present application and, therefore, should not be considered limiting of scope. For a person having ordinary skill in the art, other relevant drawings can also be obtained based on these accompanying drawings without making creative efforts.

FIG. 1 is a bottom view of a micro light-emitting diode according to an embodiment of the present application.

FIG. 2 is a schematic cross-sectional view taken along A-A of the micro light-emitting diode according to an embodiment of the present application.

FIG. 3 is a schematic cross-sectional view taken along A-A of the micro light-emitting diode according to an embodiment of the present application.

FIG. 4 is a schematic cross-sectional view taken along A-A of the micro light-emitting diode according to an embodiment of the present application.

FIG. 5 is a schematic cross-sectional view taken along A-A of the micro light-emitting diode according to an embodiment of the present application.

FIG. 6 is a schematic cross-sectional view taken along A-A of the micro light-emitting diode according to an embodiment of the present application.

FIG. 7 to FIG. 16 are schematic cross-sectional views taken along A-A of the micro light-emitting diode in different preparation stages according to an embodiment of the present application.

FIG. 17 is a schematic cross-sectional view taken along A-A of a micro light-emitting element according to an embodiment of the present application.

FIG. 18 is a schematic cross-sectional view taken along A-A of the micro light-emitting element according to an embodiment of the present application.

### DESCRIPTION OF THE DRAWINGS

10 substrate, 20 adhesive film,
100 growth substrate, 110 epitaxial layer, 110-1 rough portion, 110-2 platform portion, 111 first semiconductor layer, 112 active layer, 113 second semiconductor layer, 114 mesa, 120 first insulating layer, 130 first electrode, 140 second electrode, 150 second insulating layer, 160 protective layer, 200 first adhesive film, 300 first substrate, 400 dielectric layer, 500 second adhesive film, 600 second substrate, 700 third adhesive film, 800 third substrate, 900 step structure, 910 first step, and 920 second step.

### THE EMBODIMENTS OF THE INVENTION

### Implementation of the Invention

The implementation of the present application is illustrated below by specific embodiments. A person having ordinary skill in the art can easily understand other advantages and effects of the present application from the content disclosed in this specification. The present application can also be implemented or operated through other different specific implementation ways. The details in the present application can also be modified or changed based on different viewpoints and applications without departing from the spirit of the present application.

In the description of the present application, it should be noted that the orientation or positional relationship indicated by the terms “up”, “down”, etc. is based on the orientation or positional relationship shown in the drawings or the orientation or positional relationship that the inventive product is usually placed in use. These terms are provided to facilitate the description of the present application and simplify the description and are not intended to indicate or imply that the indicated device or element must have a specific orientation or be constructed and operated in a specific orientation, so cannot be understood as limiting the present application. Further, the terms “first”, “second”, etc. are only used to differentiate the description and should not be construed as indicating or implying relative importance.

According to one aspect of the present application, a micro light-emitting diode is provided. The micro light-emitting diode mainly refers to a micron-level light-emitting diode, and its minimum size, that is, a minimum width and minimum length ranges from 0.5 to 5 μm, 5 to 10 μm, 10 to 20 μm, 20 to 50 μm, or 50 to 100 μm.

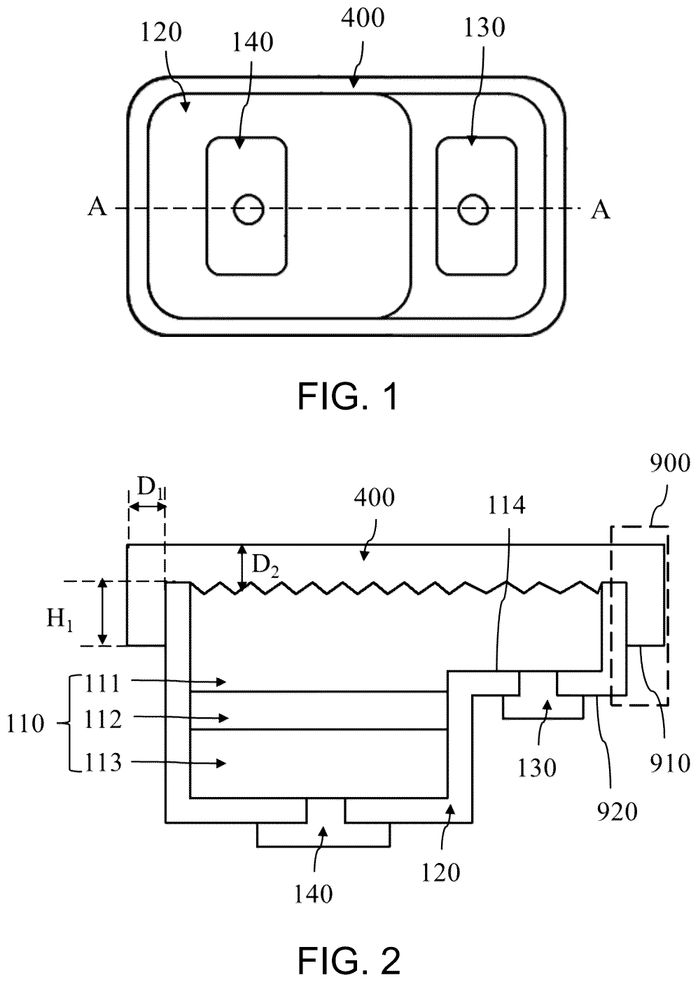

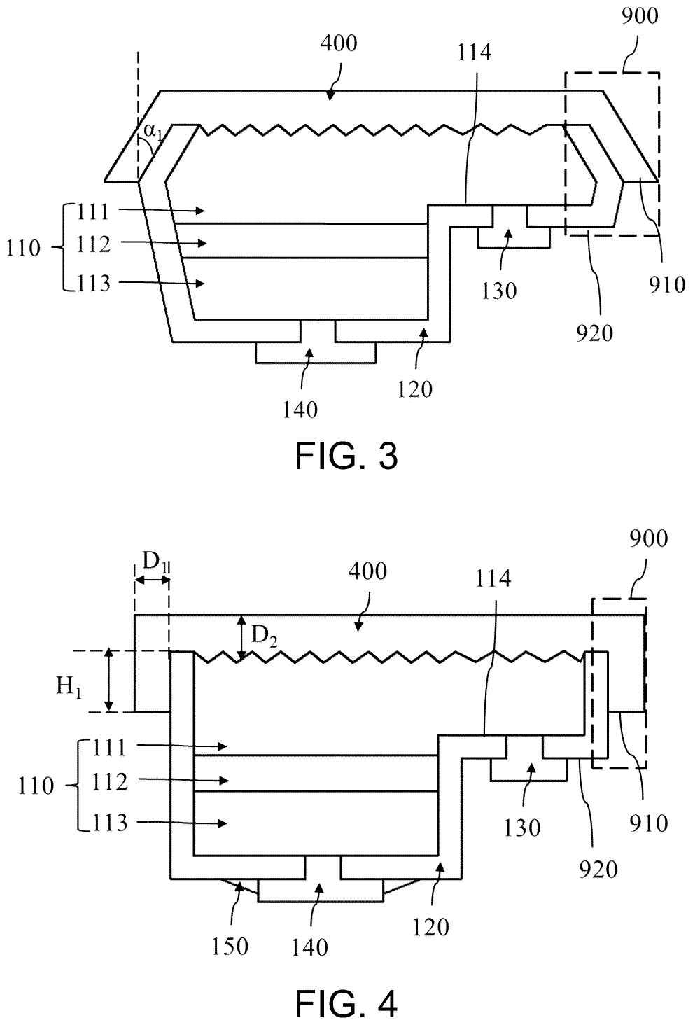

With reference to FIG. 1 and FIG. 2, the micro light-emitting diode includes an epitaxial layer 110, and a thickness of the epitaxial layer 110 is preferably 1 to 5 μm. The epitaxial layer 110 has a first surface and a second surface arranged opposite each other, and the epitaxial layer 110 includes a first semiconductor layer 111, an active layer 112, and a second semiconductor layer 113 arranged in sequence. The first semiconductor layer 111 is located on a side of the epitaxial layer 110 close to the first surface, and second semiconductor layer 113 is located on a side of the epitaxial layer 110 close to the second surface. The first surface is preferably a light-emitting surface of the micro light-emitting diode, and in order to improve the light-emitting efficiency of the micro light-emitting diode, the first surface is preferably a surface formed by roughening treatment. The second surface is configured to allow a first electrode 130 and a second electrode 140 to be arranged. The epitaxial layer 110 is configured with a mesa 114, and the mesa 114 is exposed from the first semiconductor layer 111 and faces the second surface.

The dielectric layer 400 is located on the first surface and covers the first surface and at least a portion of a side wall of the epitaxial layer 110. The thickness of the epitaxial layer 110 is relatively thin, and the first surface is preferably formed by roughening treatment, so the dielectric layer 400 is formed on the first surface and the dielectric layer 400 serves as a stress recovery layer. During the subsequent separation of a substrate from the micro light-emitting diode by using a laser lift-off process, through the arrangement of the dielectric layer 400, defects of cracks and the like of the epitaxial layer 110, especially the light-emitting surface of the micro light-emitting diode, may be avoided, or further expansion of coarsening damage on the light-emitting surface is avoided, and the reliability of the micro light-emitting diode is improved in this way.

A height H₁ of the dielectric layer 400 on the side wall of the epitaxial layer 110 is less than a height of the mesa 114, so when the second surface of the micro light-emitting diode is bonded to the substrate through an anisotropic conductive film (ACF), the anisotropic conductive film (ACF) may be prevented from swelling, and a light-emitting effect of the micro light-emitting diode is improved.

In an implementation, with reference to FIG. 2, the height H₁ of the dielectric layer 100 on the side wall of the epitaxial layer is greater than or equal to 2 μm and less than or equal to 6 μm. The height H₁ of the dielectric layer 400 on the side wall of the epitaxial layer is greater than, preferably, infinitely close to 6 μm, and as the height H₁ of the dielectric layer 400 on the side wall of the epitaxial layer increases, a required thickness of a first insulating layer 120 decreases.

A thickness D₁ of the dielectric layer 400 on the side wall of the epitaxial layer is 0 to 2 μm, and the abovementioned D₁ is preferably less than or equal to 0.8 μm. The height of the dielectric layer 400 on the side wall of the epitaxial layer is less than the height of the mesa 114 and the thickness of the dielectric layer 400 on the side wall of the epitaxial layer is relatively thin, so when the second surface of the micro light-emitting diode is bonded to the substrate through the anisotropic conductive film (ACF), the anisotropic conductive film (ACF) may be prevented from swelling, and the light-emitting effect of the micro light-emitting diode is improved.

Preferably, a thickness D₂ of the dielectric layer 400 on the first surface is greater than or equal to 0.03 μm and less than or equal to 2 μm. In this embodiment, the thickness D₂ of the dielectric layer 400 on the first surface is preferably 0.05 μm and is preferably made by atomic layer deposition.

Preferably, a material of the dielectric layer 400 includes but not limited to silicon oxide, silicon nitride, titanium oxide, aluminum oxide, or magnesium fluoride.

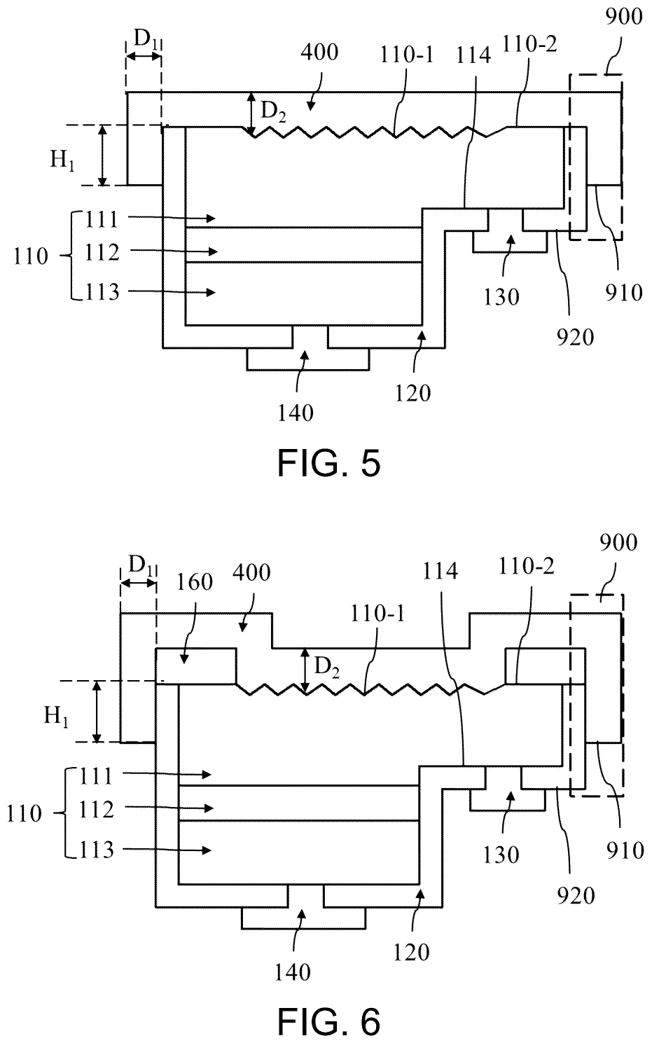

Preferably, as shown in FIG. 2, the portion of the side wall of the epitaxial layer 110 covered by the dielectric layer 400 is parallel to a vertical surface. Alternatively, as shown in FIG. 3, an angle α₁ between the portion of the side wall of the epitaxial layer 110 covered by the dielectric layer 400 and the vertical surface is between 0° and 45°, and herein, the portion of the side wall of the epitaxial layer 110 covered by the dielectric layer 400 is inclined from the lower left corner to the upper right corner. Alternatively, the angle α₁ between the portion of the side wall of the epitaxial layer covered by the dielectric layer 400 and the vertical surface is between −30° and 0°, and herein, the portion of the side wall of the epitaxial layer 110 covered by the dielectric layer 400 is inclined from the lower right corner to the upper left corner.

In an implementation, with reference to FIG. 2, the micro light-emitting diode further includes the first insulating layer 120, and the first insulating layer 120 is located on the second surface and covers the second surface and at least a portion of the side wall of the epitaxial layer 110. The first insulating layer 120 preferably covers the second surface and the entire side wall of the epitaxial layer 110, and the dielectric layer 400 extends from the first surface onto the first insulating layer 120 on the side wall of the epitaxial layer 110.

The micro light-emitting diode is configured with a step structure 900, and the step structure 900 includes a first step 910 and a second step 920. Herein, the first step 910 is formed by the dielectric layer 400, and the second step 920 is formed by the first insulating layer 120. The first step 910 exceeds the second step 920 in a horizontal direction, and a length of the first step 910 exceeding the second step 920 is equal to the thickness D₁ of the dielectric layer 400 on the side wall of the epitaxial layer. The length of the first step 910 exceeding the second step 920 is preferably less than or equal to 0.8 μm. During the subsequent removal of an adhesive film, the step structure 900 may be used to protect the first insulating layer 120, prevent the first insulating layer 120 and the epitaxial layer 110 from being damaged, and improve the reliability of the micro light-emitting diode.

In an implementation, with reference to FIG. 2, the micro light-emitting diode further includes a first electrode 130 and a second electrode 140. The first electrode 130 and the second electrode 140 are both located on the first insulating layer 120, pass through the first insulating layer 120, and are electrically connected to the first semiconductor layer 111 and the second semiconductor layer 113 respectively.

To be specific, the first insulating layer 120 includes through holes provided in the first semiconductor layer 111 and the second semiconductor layer 113. The first electrode 130 fills its corresponding through hole and is electrically connected to the first semiconductor layer 111, and the second electrode 140 fills its corresponding through hole and is electrically connected to the second semiconductor layer 113.

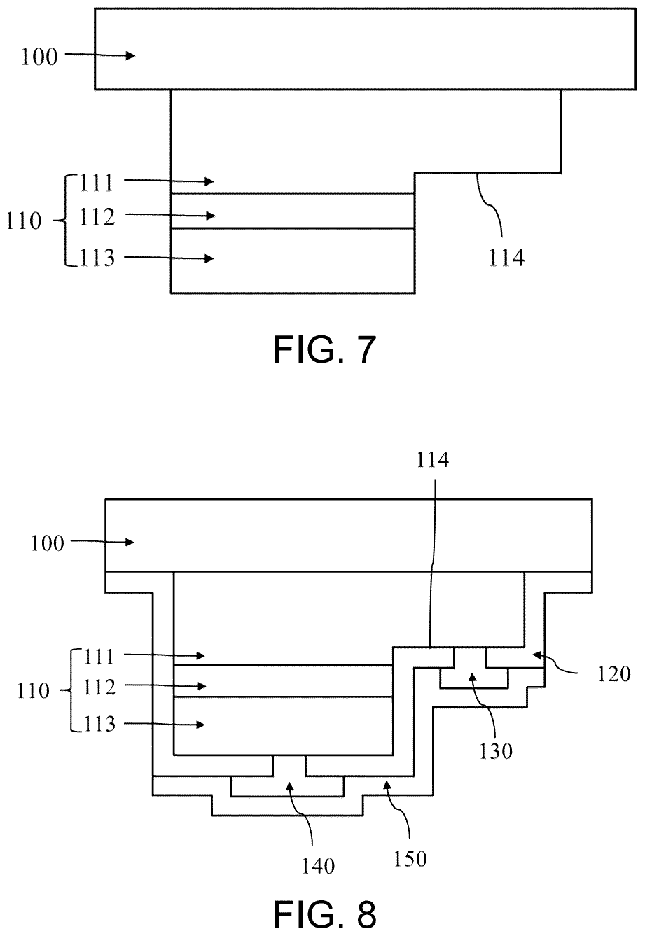

Preferably, with reference to FIG. 4, side walls of the first electrode 130 and the second electrode 140 are partially or entirely covered with a second insulating layer 150, and a thickness of the second insulating layer 150 decreases in a height direction. The thickness of the second insulating layer 150 preferably decreases from top to bottom.

Preferably, the first insulating layer 120 is made of titanium oxide, or one of the materials of the first insulating layer 120 is titanium oxide. The first insulating layer 120 is preferably a distributed Bragg reflector composed of silicon oxide and titanium oxide.

In an implementation, with reference to FIG. 2 to FIG. 4, an entire region of the first surface is configured as a rough region formed by a regular or irregular pattern, and the rough region is formed after a portion of the epitaxial layer 110 is removed, mainly to improve the light-emitting efficiency of the micro light-emitting diode.

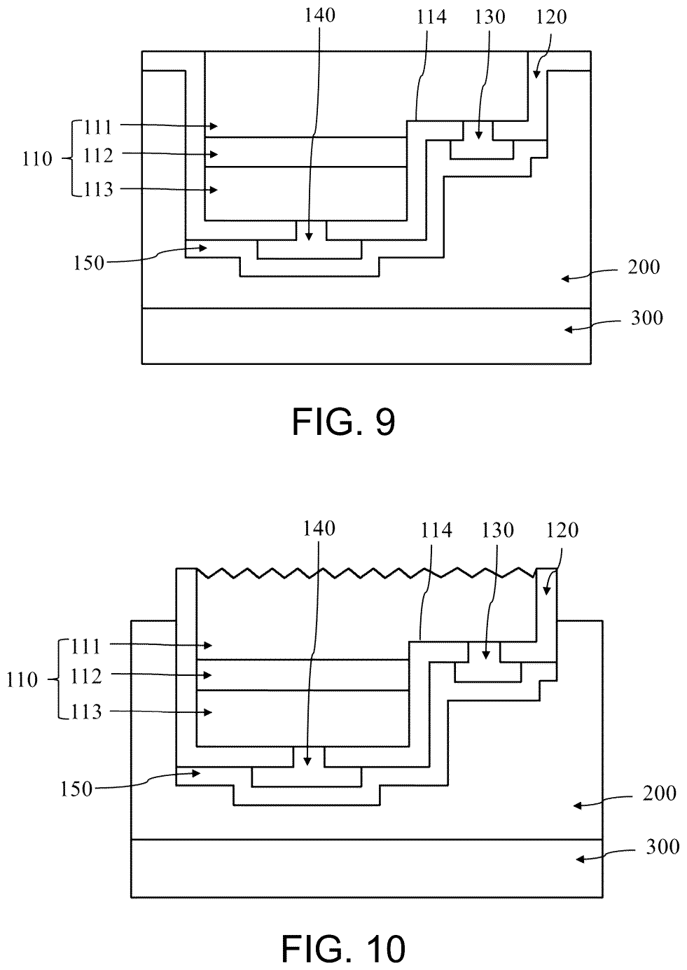

As an alternative implementation, with reference to FIG. 5, a partial region of the first surface is configured as a rough region formed by a regular or irregular pattern, and the rough region is formed after a portion of the epitaxial layer 110 is removed. To be specific, the first surface includes a rough portion 110-1 and a platform portion 110-2, the platform portion 110-2 surrounds a periphery of the rough portion 110-1, and the rough portion 110-1 is recessed toward the second surface relative to the platform portion 110-2. The rough portion 110-1 is preferably in a regular or irregular pattern.

The first insulating layer 120 is made of titanium oxide. As such, when an etching fluid is used to roughen the first surface to form the rough portion 110-1, if the first insulating layer 120 is exposed to the etching fluid, the etching fluid etches the titanium oxide in the first insulating layer 120, causing the first insulating layer 120 to fail and the light-emitting efficiency of the micro light-emitting diode to be affected. A protective layer is used to cover a partial region of the first surface in advance, and the platform portion 110-2 is formed in the region covered by the protective layer after the first surface is roughened by the etching fluid. During a formation process of the platform portion 110-2, the first insulating layer 120 at the side wall of the epitaxial layer is not exposed to the etching fluid, so that the first insulating layer 120 is prevented from being damaged to cause the first insulating layer 120 to fail, and the reliability and light-emitting efficiency of the micro light-emitting diode are improved. The abovementioned etching fluid may be an etching liquid or an etching gas, and in this embodiment, the etching fluid is preferably an etching liquid.

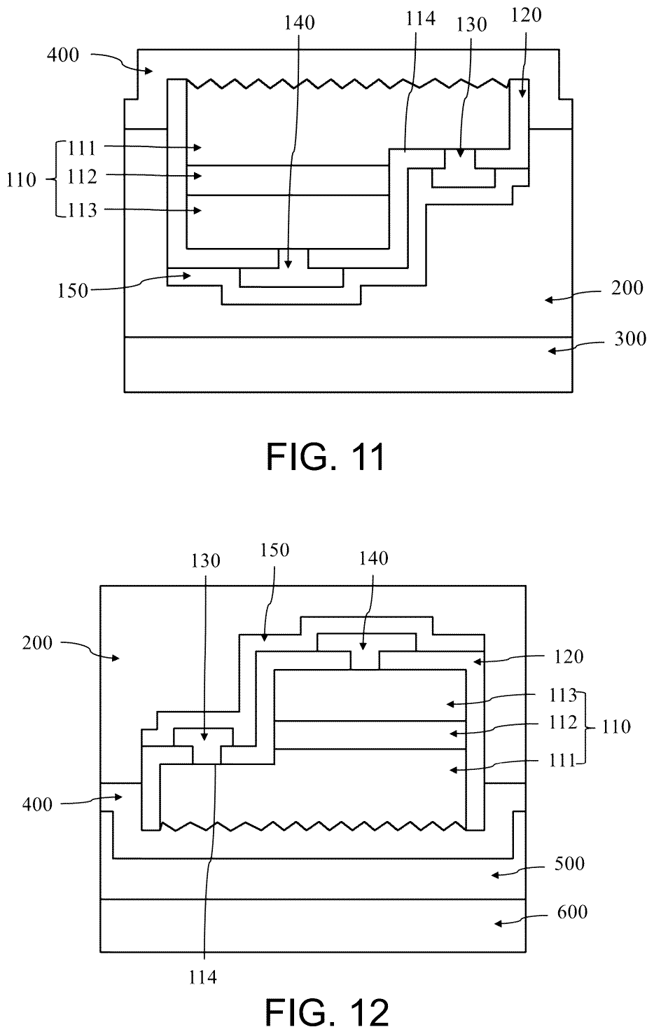

Preferably, with reference to FIG. 6, the micro light-emitting diode further includes a protective layer 160, and the protective layer 160 covers at least the platform portion 110-2. Correspondingly, the dielectric layer 400 covers the rough portion 110-1 and the protective layer 160 above the platform portion 110-2. An end portion of the protective layer 160 close to the rough portion 110-1 is preferably aligned with an end portion of the platform portion 110-2 close to the rough portion 110-1.

The protective layer 160 is made by plasma chemical vapor deposition or atomic layer deposition, and a preparation material is one or more of silicon oxide, silicon nitride, and aluminum oxide. A thickness of the protective layer 160 is preferably 10 nm to 2000 nm.

According to one aspect of the present application, a micro light-emitting diode is provided. The micro light-emitting diode has the same features as the micro light-emitting diode in the above embodiments, so the same features are not described one by one herein, and only the features that are different from that of the micro light-emitting diode in the above embodiments are described.

The micro light-emitting diode includes an epitaxial layer 110, and a thickness of the epitaxial layer 110 is preferably 1 to 5 μm. The epitaxial layer 110 has a first surface and a second surface arranged opposite each other, and the epitaxial layer 110 includes a first semiconductor layer 111, an active layer 112, and a second semiconductor layer 113 arranged in sequence. The first semiconductor layer 111 is located on a side of the epitaxial layer 110 close to the first surface, and the second semiconductor layer 113 is located on a side of the epitaxial layer 110 close to the second surface. The first surface is preferably a light-emitting surface of the micro light-emitting diode, and in order to improve the light-emitting efficiency of the micro light-emitting diode, the first surface is preferably a surface formed by roughening treatment. The second surface is configured to allow a first electrode 130 and a second electrode 140 to be arranged. The epitaxial layer 110 is configured with a mesa 114, and the mesa 114 is exposed from the first semiconductor layer 111 and faces the second surface.

The dielectric layer 400 is located on the first surface and covers the first surface. The thickness of the epitaxial layer 110 is relatively thin, and the first surface is preferably formed by roughening treatment, so the dielectric layer 400 is formed on the first surface and the dielectric layer 400 serves as a stress recovery layer. During the subsequent separation of a substrate from the micro light-emitting diode by using a laser lift-off process, through the arrangement of the dielectric layer 400, defects of cracks and the like of the epitaxial layer 110, especially the light-emitting surface of the micro light-emitting diode, may be avoided, or further expansion of coarsening damage on the light-emitting surface is avoided, and the reliability of the micro light-emitting diode is improved in this way.

According to one aspect of the present application, a preparation method for a micro light-emitting diode is provided. The preparation method includes the following steps:

In S1, an epitaxial layer 110 is formed. The epitaxial layer 110 includes a first semiconductor layer 111, an active layer 112, and a second semiconductor layer 113 arranged in sequence. The epitaxial layer 110 has a first surface and a second surface arranged opposite each other, and the first semiconductor layer 111 is located on a side of the epitaxial layer 110 close to the first surface.

In S2, the epitaxial layer 110 is etched from the second surface and a mesa 114 is formed. The mesa 114 is exposed from the first semiconductor layer 111 and faces the second surface.

In S3, a dielectric layer 400 is formed, and the dielectric layer 400 covers the first surface and extends from the first surface to a side wall of the epitaxial layer 110. A height H₁ of the dielectric layer 400 on the side wall of the epitaxial layer is less than a height of the mesa 114.

Preferably, before step S3 is performed and after step S2 is performed, the following step is also included.

A removal process, roughening treatment, or patterning treatment is performed on an entire region or a partial region of the first surface.

Preferably, before step S3 is performed and after step S2 is performed, the following steps are also included.

A first insulating layer 120 is formed. The first insulating layer 120 covers the second surface and extends from the second surface to the side wall of the epitaxial layer 110.

The first insulating layer 120 is etched, and through holes are formed to expose the second semiconductor layer 113 and the mesa 114.

A first electrode 130 is formed at the through hole corresponding to the mesa 114, and A second electrode 140 is formed at the through hole corresponding to the second semiconductor layer 113.

A second insulating layer 150 is formed. The second insulating layer 150 covers a portion of the first insulating layer 120 located on the second surface and covers the first electrode 130 and the second electrode 140.

Preferably, after step S3 is performed, the following step is also included.

The second insulating layer 150 is etched, and the first electrode 130 and the second electrode 140 are exposed. When the etching of the second insulating layer 150 is insufficient, the second insulating layer 150 partially or entirely covers side walls of the first electrode 130 and the second electrode 140.

The following is a specific example of the preparation method for the micro light-emitting diode shown in FIG. 2 to FIG. 4 in the above embodiments.

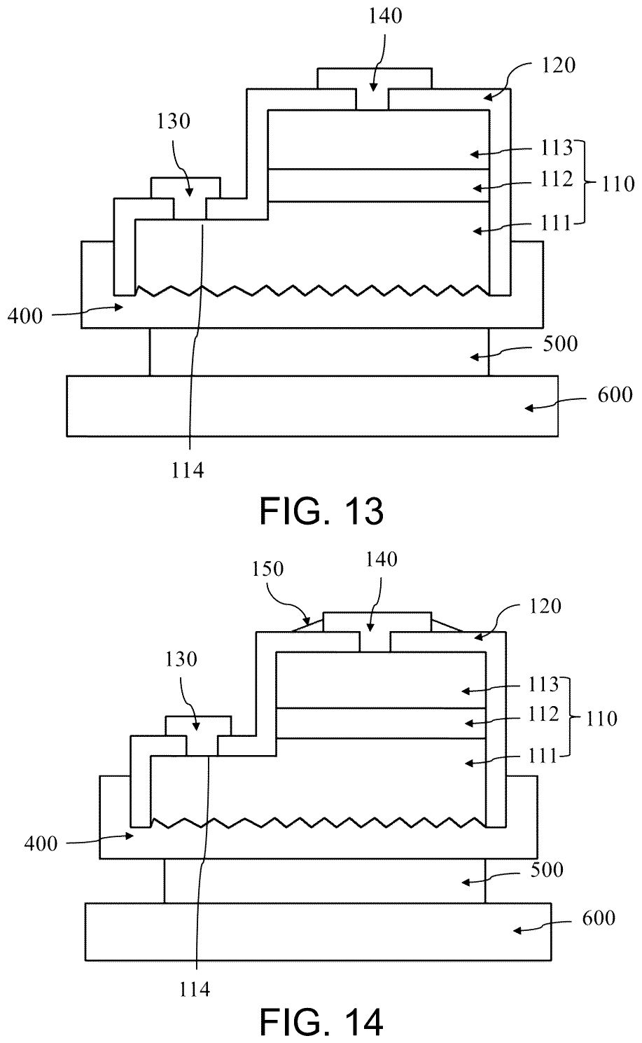

With reference to FIG. 7, a growth substrate 100 is provided. The growth substrate 100 includes a sapphire flat substrate or a sapphire patterned substrate. An epitaxial layer 110 is formed on the growth substrate 100. The epitaxial layer 110 includes a first semiconductor layer 111, an active layer 112, and a second semiconductor layer 113 arranged in sequence. The first semiconductor layer 111 is located on a side close to the growth substrate 100, that is, a first surface is located on a side close to the growth substrate 100.

The epitaxial layer 110 is etched and a mesa 114 is formed. The mesa 114 is exposed from the first semiconductor layer 111 and faces a second surface.

With reference to FIG. 8, a first insulating layer 120 is formed on the second surface. The first insulating layer 120 covers the second surface and extends from the second surface to a side wall of the epitaxial layer 110. The first insulating layer 120 is etched, and through holes are formed to expose the second semiconductor layer 113 and the mesa 114.

A first electrode 130 is formed at the through hole corresponding to the mesa 114, and the first electrode 130 is electrically connected to the first semiconductor layer 111. A second electrode 140 is formed at the through hole corresponding to the second semiconductor layer 113. and the second electrode 140 is electrically connected to the second semiconductor layer 113.

A second insulating layer 150 is formed on the first insulating layer 120. The second insulating layer 150 covers a portion of the first insulating layer 120 located on the second surface and covers the first electrode 130 and the second electrode 140.

Preferably, the first insulating layer 120 and the second insulating layer 150 are both made of titanium oxide, or one of the materials of the first insulating layer 120 and the second insulating layer 150 is titanium oxide. Both the first insulating layer 120 and the second insulating layer 150 are preferably distributed Bragg reflectors composed of silicon oxide and titanium oxide.

With reference to FIG. 9, a first adhesive film 200 is formed on the second insulating layer 150 and a region of the first insulating layer 120 where the second insulating layer 150 is not provided, and the epitaxial layer 110 is fixed on a first substrate 300 through the first adhesive film 200. The growth substrate 100 is removed and the first surface is exposed. The first adhesive film 200 is made of polyimide or acrylic adhesive, and the polyimide or acrylic adhesive can pass through laser in the ultraviolet band and can be fully decomposed by laser in the ultraviolet band, so the micro light-emitting diode is ensured not to be damaged by laser. Preferably, the polyimide or acrylic adhesive may at least partially absorb laser with a wavelength of 360 nm or less, and its transmittance to laser with a wavelength of 360 nm or less is not less than 90%.

With reference to FIG. 10, the first adhesive film 200 is partially removed, and the removal height of the first adhesive film 200 is controllable. By controlling a removal height of the first adhesive film 200, a height of the subsequently formed dielectric layer 400 on the side wall of the epitaxial layer can be controlled to further control the coverage and protection of the insulating layer 120 at the side wall of the epitaxial layer by the dielectric layer 400.

The first surface is roughened by wet etching or dry etching. In this embodiment, the roughening treatment of the first surface is preferably a wet etching method.

With reference to FIG. 11, the dielectric layer 400 is formed on the first surface and the remaining first adhesive film 200, and the dielectric layer 400 extends from the first surface through the first insulating layer 120 at the side wall of the epitaxial layer onto the first adhesive film 200. A height H₁ of the dielectric layer 400 on the side wall of the epitaxial layer 110 is less than a height of the mesa 114.

Preferably, the height H₁ of the dielectric layer 400 on the side wall of the epitaxial layer is greater than or equal to 2 μm and less than or equal to 6 μm. H₁ is greater than, preferably, infinitely close to 6 μm, and as H₁ increases, a thickness of the first insulating layer 120 decreases.

Preferably, a thickness D₁ of the dielectric layer 400 on the side wall of the epitaxial layer is 0 to 2 μm, and the abovementioned D₁ is preferably less than or equal to 0.8 μm. A thickness D₂ of the dielectric layer 400 on the first surface is greater than or equal to 0.03 μm and less than or equal to 2 μm.

Preferably, a material of the dielectric layer 400 includes but not limited to silicon oxide, silicon nitride, titanium oxide, aluminum oxide, or magnesium fluoride.

Preferably, the portion of the side wall of the epitaxial layer 110 covered by the dielectric layer 400 is parallel to a vertical surface. Alternatively, an angle α₁ between the portion of the side wall of the epitaxial layer 110 covered by the dielectric layer 400 and the vertical surface is 0° to 45°, and herein, the portion of the side wall of the epitaxial layer 110 covered by the dielectric layer 400 is inclined from the lower left corner to the upper right corner. Alternatively, the angle α₁ between the portion of the side wall of the epitaxial layer covered by the dielectric layer 400 and the vertical surface is between −30° and 0°, and herein, the portion of the side wall of the epitaxial layer 110 covered by the dielectric layer 400 is inclined from the lower right corner to the upper left corner.

With reference to FIG. 12, a second adhesive film 500 is formed on the dielectric layer 400, and the epitaxial layer 110 is fixed on a second substrate 600 through the second adhesive film 500. The first substrate 300 is removed, and during the separation process of the first substrate 300 and the epitaxial layer 110, the dielectric layer 400 may serve as a stress recovery layer. In this way, defects of cracks and the like in the epitaxial layer 110 may be avoided, or the coarsening damage in the first surface may be prevented from further expanding, and the reliability of the micro light-emitting diode can be improved. The second adhesive film 500 is made of polyimide or acrylic adhesive, and the polyimide or acrylic adhesive can pass through laser in the ultraviolet band and can be fully decomposed by laser in the ultraviolet band, so the micro light-emitting diode is ensured not to be damaged by laser. Preferably, the polyimide or acrylic adhesive may at least partially absorb laser with a wavelength of 360 nm or less, and its transmittance to laser with a wavelength of 360 nm or less is not less than 90%.

With reference to FIG. 13, the second adhesive film 500 is partially removed. A width of the remaining second adhesive film 500 is less than a width of the epitaxial layer 110, and a length of the remaining second adhesive film 500 is less than a length of the epitaxial layer 110. During the removal process of the second adhesive film 500, since the dielectric layer 400 covers a portion of the side wall of the epitaxial layer 100, the dielectric layer 400 well covers the first insulating layer 120 on the side wall of the epitaxial layer, so the first insulating layer 120, especially the epitaxial layer 110, may be prevented from being damaged.

During the removal process of the second adhesive film 500, the second adhesive film 500 above the second surface is also removed, and the second insulating layer 150 is removed at the same time to expose the first electrode 130 and the second electrode 140. For instance, as shown in FIG. 13, the second insulating layer 150 is entirely removed. Alternatively, as shown in FIG. 14, the etching of the second insulating layer 150 is insufficient, the second insulating layer 150 partially or entirely covers side walls of the first electrode 130 and the second electrode 140.

With reference to FIG. 15, a third adhesive film 700 is formed on the second surface, and the epitaxial layer 110 is fixed on a third substrate 800 through the third adhesive film 700. The third adhesive film 700 is preferably an anisotropic conductive film (ACF), and the first electrode 130 and the second electrode 140 are electrically connected to the third substrate 800 through the third adhesive film 700. The second substrate 600 is removed.

Since the height of the dielectric layer 400 on the side wall of the epitaxial layer is less than the height of the mesa 114 and the thickness of the dielectric layer 400 on the side wall of the epitaxial layer is relatively thin, the third adhesive film 700 may be prevented from swelling, and the light-emitting effect of the micro light-emitting diode is improved.

With reference to FIG. 16, the remaining second adhesive film 500 is removed. The third adhesive film 700 is partially removed. A width of the remaining third adhesive film 700 is less than the width of the epitaxial layer 110, and a length of the remaining third adhesive film 700 is less than the length of the epitaxial layer 110.

After the above operations are completed, the third substrate 800 is removed to obtain the micro light-emitting diode in FIG. 2 to FIG. 4.

It should be noted that to prepare the micro light-emitting diode shown in FIG. 5, it is only necessary to form the protective layer 160 on a portion of the first surface before the first surface is roughened by wet etching or dry etching and remove the protective layer 160 after the first surface is roughened by wet etching or dry etching.

It should be noted that to prepare the micro light-emitting diode shown in FIG. 6, it is only necessary to form the protective layer 160 on a portion of the first surface before the first surface is roughened by wet etching or dry etching.

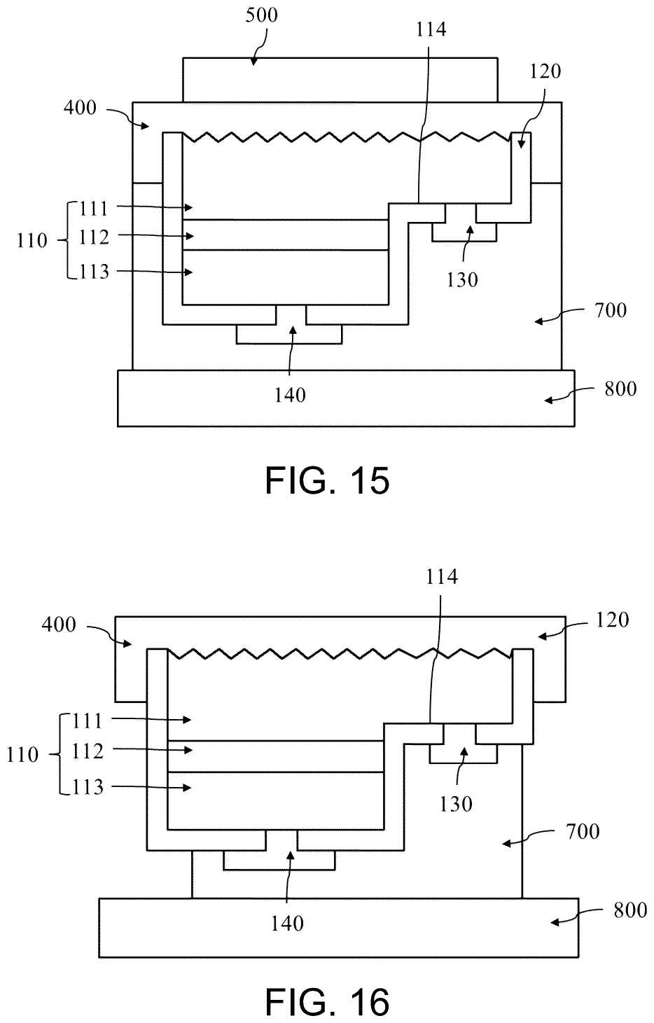

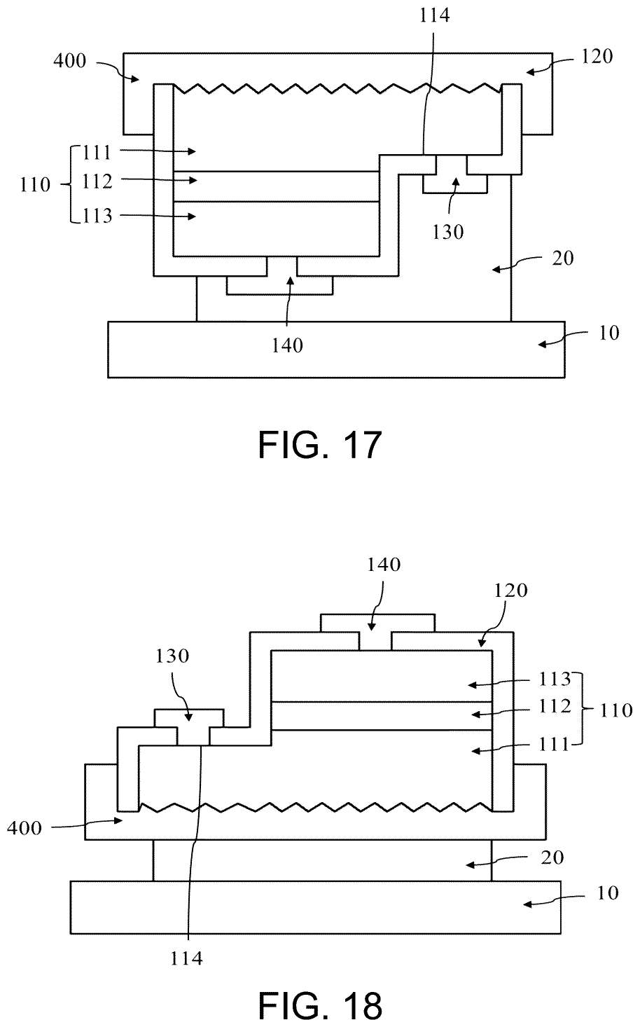

According to one aspect of the present application, a micro light-emitting element is provided. The micro light-emitting element includes a substrate 10 and at least one micro light-emitting diode arranged on the substrate 10, and the micro light-emitting diode is the micro light-emitting diode in the above embodiments. The first surface of the epitaxial layer 110 in the micro light-emitting diode faces the substrate 10, or the first surface of the epitaxial layer 110 in the micro light-emitting diode faces away from the substrate 10. An adhesive film 20 is located between the substrate 10 and the micro light-emitting diode, and a width of the adhesive film 20 is less than the width of the epitaxial layer 100. FIG. 17 and FIG. 18 only illustrate the micro light-emitting element composed of the micro light-emitting diode shown in FIG. 2, and the micro light-emitting element composed of the micro light-emitting diode shown in FIG. 3 to FIG. 6 is also within the protection scope of the present application.

The micro light-emitting diode includes an epitaxial layer 110, and a thickness of the epitaxial layer 110 is preferably 1 to 5 μm. The epitaxial layer 110 has a first surface and a second surface arranged opposite each other, and the epitaxial layer 110 includes a first semiconductor layer 111, an active layer 112, and a second semiconductor layer 113 arranged in sequence. The first semiconductor layer 111 is located on a side of the epitaxial layer 110 close to the first surface, and the second semiconductor layer 113 is located on a side of the epitaxial layer 110 close to the second surface. The first surface is preferably the light-emitting surface of the micro light-emitting diode, and in order to improve the light-emitting efficiency of the micro light-emitting element, the first surface is preferably a surface formed by roughening treatment. The second surface is configured to allow a first electrode 130 and a second electrode 140 to be arranged. The epitaxial layer 110 is configured with a mesa 114, and the mesa 114 is exposed from the first semiconductor layer 111 and faces the second surface.

The dielectric layer 400 is located on the first surface and covers the first surface and at least a portion of a side wall of the epitaxial layer 110. The thickness of the epitaxial layer 110 is relatively thin, and the first surface is preferably formed by roughening treatment, so the dielectric layer 400 is formed on the first surface and the dielectric layer 400 serves as a stress recovery layer. During the subsequent separation of a substrate from the micro light-emitting diode by using a laser lift-off process, through the arrangement of the dielectric layer 400, defects of cracks and the like of the epitaxial layer 110, especially the light-emitting surface of the micro light-emitting diode, may be avoided, or further expansion of coarsening damage on the light-emitting surface is avoided, and the reliability of the micro light-emitting diode and the micro light-emitting element is improved in this way.

A height H₁ of the dielectric layer 400 on the side wall of the epitaxial layer 110 is less than a height of the mesa 114, so when the second surface of the micro light-emitting diode is bonded to the substrate through an anisotropic conductive film (ACF), the anisotropic conductive film (ACF) may be prevented from swelling, and a light-emitting effect of the micro light-emitting diode and the micro light-emitting element is improved.

In an implementation, the substrate 10 includes but not limited to a sapphire substrate, glass, a silicon substrate, or a silicon carbide substrate. The adhesive film 20 is made of polyimide or acrylic adhesive, and the polyimide or acrylic adhesive can pass through laser in the ultraviolet band and can be fully decomposed by laser in the ultraviolet band, so the micro light-emitting diode is ensured not to be damaged by laser. Preferably, the polyimide or acrylic adhesive may at least partially absorb laser with a wavelength of 360 nm or less, and its transmittance to laser with a wavelength of 360 nm or less is not less than 90%.

When the first surface of the epitaxial layer 110 in the micro light-emitting diode faces away from the substrate 10, the adhesive film 20 is preferably an anisotropic conductive film (ACF).

When the first surface of the epitaxial layer 110 in the micro light-emitting diode faces the substrate 10, the substrate 10 is preferably a transparent substrate, and the transparent substrate includes but not limited to a sapphire substrate or a glass substrate.

In an implementation, the height H₁ of the dielectric layer 100 on the side wall of the epitaxial layer is greater than or equal to 2 μm and less than or equal to 6 μm. The height H₁ of the dielectric layer 400 on the side wall of the epitaxial layer is greater than, preferably, infinitely close to 6 μm, and as the height H₁ of the dielectric layer 400 on the side wall of the epitaxial layer increases, a required thickness of a first insulating layer 120 decreases.

A thickness D₁ of the dielectric layer 400 on the side wall of the epitaxial layer is 0 to 2 μm, and the abovementioned D₁ is preferably less than or equal to 0.8 μm. Since the height of the dielectric layer 400 on the side wall of the epitaxial layer is less than the height of the mesa 114 and the thickness of the dielectric layer 400 on the side wall of the epitaxial layer is relatively thin, when the second surface of the micro light-emitting diode is bonded to the substrate through an anisotropic conductive film (ACF), the anisotropic conductive film (ACF) may be prevented from swelling, and the light-emitting effect of the micro light-emitting diode and the micro light-emitting element is improved.

Preferably, a thickness D₂ of the dielectric layer 400 on the first surface is greater than or equal to 0.03 μm and less than or equal to 2 μm. In this embodiment, the thickness D₂ of the dielectric layer 400 on the first surface is preferably 0.05 μm and is preferably made by atomic layer deposition.

Preferably, a material of the dielectric layer 400 includes but not limited to silicon oxide, silicon nitride, titanium oxide, aluminum oxide, or magnesium fluoride.

Preferably, the portion of the side wall of the epitaxial layer 110 covered by the dielectric layer 400 is parallel to a vertical surface. Alternatively, an angle α₁ between the portion of the side wall of the epitaxial layer 110 covered by the dielectric layer 400 and the vertical surface is 0° to 45°, and herein, the portion of the side wall of the epitaxial layer 110 covered by the dielectric layer 400 is inclined from the lower left corner to the upper right corner. Alternatively, the angle α₁ between the portion of the side wall of the epitaxial layer covered by the dielectric layer 400 and the vertical surface is between −30° and 0°, and herein, the portion of the side wall of the epitaxial layer 110 covered by the dielectric layer 400 is inclined from the lower right corner to the upper left corner.

In an implementation, the micro light-emitting diode further includes the first insulating layer 120, and the first insulating layer 120 is located on the second surface and covers the second surface and at least a portion of the side wall of the epitaxial layer 110. The first insulating layer 120 preferably covers the second surface and the entire side wall of the epitaxial layer 110, and the dielectric layer 400 extends from the first surface onto the first insulating layer 120 on the side wall of the epitaxial layer 110.

The micro light-emitting diode is configured with a step structure 900, and the step structure 900 includes a first step 910 and a second step 920. Herein, the first step 910 is formed by the dielectric layer 400, and the second step 920 is formed by the first insulating layer 120. The first step 910 exceeds the second step 920 in a horizontal direction, and a length of the first step 910 exceeding the second step 920 is equal to the thickness D₁ of the dielectric layer 400 on the side wall of the epitaxial layer. The length of the first step 910 exceeding the second step 920 is preferably less than or equal to 0.8 μm. During the subsequent removal of an adhesive film, the step structure 900 may be used to protect the first insulating layer 120, prevent the first insulating layer 120 and the epitaxial layer 110 from being damaged, and improve the reliability of the micro light-emitting diode and the micro light-emitting element.

In an implementation, the micro light-emitting diode further includes a first electrode 130 and a second electrode 140. The first electrode 130 and the second electrode 140 are both located on the first insulating layer 120, pass through the first insulating layer 120, and are electrically connected to the first semiconductor layer 111 and the second semiconductor layer 113 respectively.

To be specific, the first insulating layer 120 includes through holes provided in the first semiconductor layer 111 and the second semiconductor layer 113. The first electrode 130 fills its corresponding through hole and is electrically connected to the first semiconductor layer 111. and the second electrode 140 fills its corresponding through hole and is electrically connected to the second semiconductor layer 113.

Preferably, side walls of the first electrode 130 and the second electrode 140 are partially or entirely covered with a second insulating layer 150, and a thickness of the second insulating layer 150 decreases in a height direction. The thickness of the second insulating layer 150 preferably decreases from top to bottom.

Preferably, the first insulating layer 120 is made of titanium oxide, or one of the materials of the first insulating layer 120 is titanium oxide. The first insulating layer 120 is preferably a distributed Bragg reflector composed of silicon oxide and titanium oxide.

In an implementation, an entire region of the first surface is configured as a rough region formed by a regular or irregular pattern, and the rough region is formed after a portion of the epitaxial layer 110 is removed, mainly to improve the light-emitting efficiency of the micro light-emitting diode and the micro light-emitting element.

As an alternative implementation, a partial region of the first surface is configured as a rough region formed by a regular or irregular pattern, and the rough region is formed after a portion of the epitaxial layer 110 is removed. To be specific, the first surface includes a rough portion 110-1 and a platform portion 110-2, the platform portion 110-2 surrounds a periphery of the rough portion 110-1, and the rough portion 110-1 is recessed toward the second surface relative to the platform portion 110-2. The rough portion 110-1 is preferably in a regular or irregular pattern.

The first insulating layer 120 is made of titanium oxide. As such, when an etching fluid is used to roughen the first surface to form the rough portion 110-1, if the first insulating layer 120 is exposed to the etching fluid, the etching fluid etches the titanium oxide in the first insulating layer 120, causing the first insulating layer 120 to fail and the light-emitting efficiency of the micro light-emitting diode to be affected. A protective layer is used to cover a partial region of the first surface in advance, and the platform portion 110-2 is formed in the region covered by the protective layer after the first surface is roughened by the etching fluid. During a formation process of the platform portion 110-2, the first insulating layer 120 at the side wall of the epitaxial layer is not exposed to the etching fluid, so that the first insulating layer 120 is prevented from being damaged to cause the first insulating layer 120 to fail, and the reliability and light-emitting efficiency of the micro light-emitting diode are improved. The abovementioned etching fluid may be an etching liquid or an etching gas, and in this embodiment, the etching fluid is preferably an etching liquid.

Preferably, the micro light-emitting diode further includes a protective layer 160, and the protective layer 160 covers at least the platform portion 110-2. Correspondingly, the dielectric layer 400 covers the rough portion 110-1 and the protective layer 160 above the platform portion 110-2. An end portion of the protective layer 160 close to the rough portion 110-1 is preferably aligned with an end portion of the platform portion 110-2 close to the rough portion 110-1.

The protective layer 160 is made by plasma chemical vapor deposition or atomic layer deposition, and a preparation material is one or more of silicon oxide, silicon nitride, and aluminum oxide. A thickness of the protective layer 160 is preferably 10 nm to 2000 nm.

According to one aspect of the present application, a display is provided, and the display includes a base having a driving circuit and at least one micro light-emitting diode arranged on the base according to the abovementioned embodiments. A first electrode 130 and a second electrode 140 in the micro light-emitting diode face a base 30 and are electrically connected to the driving circuit. The structure of the micro light-emitting diode is the same as the structure of the micro light-emitting diode in the above embodiments, so description thereof is not repeated herein.

It can be seen from the above technical solutions that the dielectric layer 400 is arranged on the first surface of the epitaxial layer 110 and the dielectric layer 400 can serve as a stress recovery layer, such that during the separation of the substrate from the micro light-emitting diode by using a laser lift-off process, the defects of cracks and the like of the epitaxial layer 110 are avoided, or coarsening damage caused by an etching process to the epitaxial layer 110 is prevented from further expanding. The reliability of the micro light-emitting diode is thus improved.

Further, the micro light-emitting diode is configured with the step structure 900, and the step structure 900 includes the first step 910 and the second step 920. Herein, the first step 910 is formed by the dielectric layer 400, and the second step 920 is formed by the first insulating layer 120. The first step 910 exceeds the second step 920 in the horizontal direction, and the length of the first step 910 exceeding the second step 920 is equal to the thickness D₁ of the dielectric layer 400 on the side wall of the epitaxial layer. During the removal of the adhesive film, the step structure may be used to protect the first insulating layer 120, prevent the first insulating layer 120 and the epitaxial layer 110 from being damaged, and improve the reliability of the micro light-emitting diode. Further, the height of the dielectric layer 400 on the side wall of the epitaxial layer is less than the height of the mesa 114 and the thickness of the dielectric layer 400 on the side wall of the epitaxial layer is relatively thin, so when the second surface of the micro light-emitting diode is bonded to the substrate through the adhesive film, the adhesive film may be prevented from swelling, and the light-emitting effect of the micro light-emitting diode is improved.

The above are only the preferred embodiments of the present application, and it should be noted that a person having ordinary skill in the art can make several improvements and substitutions without departing from the technical principles of the present application, and these improvements and substitutions should also be regarded as the protection scope of the present application.

1. A micro light-emitting diode, comprising:
an epitaxial layer comprising a first semiconductor layer, an active layer, and a second semiconductor layer arranged in sequence, wherein the epitaxial layer has a first surface and a second surface arranged opposite each other, the first semiconductor layer is located on a side of the epitaxial layer close to the first surface, the epitaxial layer is configured with a mesa, and the mesa is exposed from the first semiconductor layer and faces the second surface; and
a dielectric layer covering the first surface and at least a portion of a side wall of the epitaxial layer, wherein a height H1 of the dielectric layer on the side wall of the epitaxial layer is less than a height of the mesa.

2. The micro light-emitting diode according to claim 1, wherein the height H1 of the dielectric layer on the side wall of the epitaxial layer is greater than or equal to 2 μm and less than or equal to 6 μm.

3. The micro light-emitting diode according to claim 1, wherein a thickness D1 of the dielectric layer on the side wall of the epitaxial layer is greater than 0 μm and less than or equal to 2 μm.

4. The micro light-emitting diode according to claim 1, wherein a thickness D2 of the dielectric layer on the first surface is greater than or equal to 0.03 μm and less than or equal to 2 μm.

5. The micro light-emitting diode according to claim 1, wherein a material of the dielectric layer comprises silicon oxide, silicon nitride, titanium oxide, aluminum oxide, or magnesium fluoride.

6. The micro light-emitting diode according to claim 1, wherein at least a partial region of the first surface is configured as a rough region formed by a regular or irregular pattern, and the rough region is formed after a portion of the epitaxial layer is removed.

7. The micro light-emitting diode according to claim 1, wherein the first surface comprises a rough portion and a platform portion, the platform portion surrounds a periphery of the rough portion, and the rough portion is recessed toward the second surface relative to the platform portion.

8. The micro light-emitting diode according to claim 1, further comprising:
a first insulating layer covering the second surface and at least a portion of the side wall of the epitaxial layer; and
a step structure comprising a first step formed by the dielectric layer and a second step formed by the first insulating layer, wherein the first step exceeds the second step in a horizontal direction, and a width of the first step exceeding the second step is equal to the thickness D1 of the dielectric layer on the side wall of the epitaxial layer.

9. The micro light-emitting diode according to claim 8, further comprising:
a first electrode electrically connected to the first semiconductor layer; and
a second electrode electrically connected to the second semiconductor layer.

10. The micro light-emitting diode according to claim 9, wherein side walls of the first electrode and the second electrode are partially or entirely covered with a second insulating layer, and a thickness of the second insulating layer decreases in a height direction.

11. The micro light-emitting diode according to claim 1, wherein a minimum size of the micro light-emitting diode is 0.5 to 5 μm, 5 to 10 μm, 10 to 20 μm, 20 to 50 μm, or 50 to 100 μm.

12. The micro light-emitting diode according to claim 1, wherein a thickness of the epitaxial layer is 1 to 5 μm.

13. The micro light-emitting diode according to claim 1, wherein an angle between the portion of the side wall of the epitaxial layer covered by the dielectric layer and a vertical surface is between 0° and 45°, or the angle between the portion of the side wall of the epitaxial layer covered by the dielectric layer and the vertical surface is between −30° and 0°.

14. A preparation method for a micro light-emitting diode, comprising:
forming an epitaxial layer comprising a first semiconductor layer, an active layer, and a second semiconductor layer arranged in sequence, wherein the epitaxial layer has a first surface and a second surface arranged opposite each other, and the first semiconductor layer is located on a side of the epitaxial layer close to the first surface;
etching the epitaxial layer from the second surface and forming a mesa, wherein the mesa is exposed from the first semiconductor layer and faces the second surface; and
forming a dielectric layer covering the first surface and extending from the first surface to a side wall of the epitaxial layer, wherein a height H1 of the dielectric layer on the side wall of the epitaxial layer is less than a height of the mesa.

15. The preparation method for the micro light-emitting diode according to claim 14, wherein before the dielectric layer is formed and after the epitaxial layer is etched and the mesa is formed, further comprising:
performing a removal process, roughening treatment, or patterning treatment on an entire region or a partial region of the first surface.

16. A micro light-emitting element, comprising:
a substrate;
at least one micro light-emitting diode arranged on the substrate, each of the micro light-emitting diode comprising:
an epitaxial layer comprising a first semiconductor layer, an active layer, and a second semiconductor layer arranged in sequence, wherein the epitaxial layer has a first surface and a second surface arranged opposite each other, the first semiconductor layer is located on a side of the epitaxial layer close to the first surface, the epitaxial layer is configured with a mesa, the mesa is exposed from the first semiconductor layer and faces the second surface, and the first surface faces or faces away from the substrate;
a dielectric layer covering the first surface and at least a portion of a side wall of the epitaxial layer, wherein a height H1 of the dielectric layer on the side wall of the epitaxial layer is less than a height of the mesa; and
an adhesive film located between the substrate and the micro light-emitting diode, wherein a width of the adhesive film is less than a width of the epitaxial layer.

17. The micro light-emitting element according to claim 16, wherein the substrate comprises a transparent substrate, and the transparent substrate comprises a sapphire substrate or a glass substrate.

18. The micro light-emitting element according to claim 16, wherein the height H1 of the dielectric layer on the side wall of the epitaxial layer is greater than or equal to 2 μm and less than or equal to 6 μm, a thickness DI of the dielectric layer on the side wall of the epitaxial layer is greater than 0 μm and less than or equal to 2 μm, and a thickness D2 of the dielectric layer on the first surface is greater than or equal to 0.03 μm and less than or equal to 2 μm.

19. The micro light-emitting element according to claim 16, wherein at least a partial region of the first surface is configured as a rough region formed by a regular or irregular pattern, and the rough region is formed after a portion of the epitaxial layer is removed.

20. A display, comprising a base having a driving circuit and at least one micro light-emitting diode arranged on the base according to claim 1, wherein the micro light-emitting diode is electrically connected to the driving circuit.
